(19) United States
(12) Patent Application Publication
(10) Pub. No.: US 2007/0090519 A1
(43) Pub. Date: Apr. 26, 2007

(54) Encased thermal management device and method of making such a device

(76) Inventors: Antony Arthur Carter, London (GB); Rui De Oliveira, Arenthon (FR)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 10/554,567

(22) PCT Filed: Apr. 30, 2004
(86) PCT No.: PCT/GB04/01886

§ 371 Date: Aug. 30, 2006

(30) Foreign Application Priority Data
May 1, 2003 (GB) 0310093.0

(51) Int. Cl. H01L 23/34

(52) U.S. Cl. 257/712

(57) ABSTRACT

A thermal management device comprises an electronic device (20) encased in thermal management structures (10, 26, 28) comprising anisotropic carbon encapsulated in an encapsulating material.

The present invention relates to a thermal management device for managing the dissipation of heat in, for example, electronic equipment and a method of making such a device. In particular, the invention relates to a thermal management device for an electronic device.

Electronic and electrical devices are the sources of both power and heat. As is well known, in order to provide reliable operation of such devices, it is necessary to maintain stable operating conditions and temperatures. Hence, efficient methods for heat management and dissipation are essential. Typically this is done by providing thermal management devices that are arranged adjacent and in contact with the electronic device or circuit board. Heat generated in the circuit is transferred to and dissipated in the thermal management device. For optimum efficiency, it is desirable that thermal management structures have the highest possible thermal conductivity, efficient external connectivity and appropriate mechanical strength.

To achieve these objectives in thermally demanding applications, some known devices encapsulate high thermal conductivity materials into composite structures. However, these devices often achieve only limited performance, with significant conductivity losses, typically 40%, and increases in mass and bulk.

A further problem is that the mass and volume of known thermal management systems are relatively large. This affects the overall size of electronic systems in which such devices are incorporated. In this day and age when the general drive of the electronics industry is towards miniaturisation, this is highly disadvantageous.

Thermal management systems are often used as substrates for supports for hybrid electronic circuits. In one known arrangement, beryllia is used as a heat sink. This has a thermal conductivity of around 280 W/mK at room temperature. On top of this dielectric gold contacts are subsequently formed, thereby to enable connection to other electrical circuits. A disadvantage of this arrangement is that beryllia is a hazardous material; in fact it is carcinogenic, and is generally difficult to process. In addition, the dielectric tends to be thick thereby making the overall structure bulky. Furthermore, partly because of the use of gold as a contact material, the overall structure is expensive to manufacture.

One known solution is that described in International patent application no. WO00/03567 the contents of which are incorporated herein by reference. According to the approach described in that document a plate of anisotropic carbon, for example pyrolitic graphite or thermalised pyrolitic graphite is encapsulated in an encapsulating material such as polyimide or epoxy resin or acrylic or polyurethane or polyester or any other suitable polymer. The encapsulating material is applied directly to the anisotropic carbon and improves the rigidity of the carbon. The resulting device has an in-plane thermal conductivity of typically 1,700 W/mK at room temperature whilst providing a flatness which may be at typically plus or minus 5 μm across a plate that is 100 mm by 100 mm. Yet further the device can provide a board having a tensile strength that is significantly higher than that of the original, unencapsulated, carbon plate with a negligible increase in volume and loss of thermal conductivity.

With, for example, power semi-conductors, current and power ratings are directly linked to the thermal environment, and a heat exchanging interface is needed to control junction temperatures below their rated limit. The failure rate of such power devices in industry has been shown to decrease by about 50% for a junction temperature decrease of around 20° C. for operating conditions in the region 100° C. to 130° C., and even larger improvements can be made in the mean-time-to-failure statistics. Various factors affect reliability, including faulty mounting between the semi conductor and the heat sink, arc-over for high voltage operation, the requirement for an isolated or ground interface between the semi conductor chip base and its heat sink and mechanical damage of plastic packaged semi conductors.

These factors give rise to various problems. Faulty mountings are a major cause of early failure, arising from excessive junction temperatures and existing techniques require high quality, and costly surface finishes for each component to deal with these problems. In order to avoid arc-over, in current solutions interface-separation specifications are required between source and sink but further diminish thermal transfer efficiencies and can require the use of thermal grease. Mechanical damage can give rise to damage to internal bond wires, destruction of package integrity to water resistance and the possibility of die-fracture and current solutions require combinations of costly and complex operations. As a result yet further improved thermal management devices are required.

The invention is set out in the accompanying claims. An electrical device is encased in a thermal management device comprising anisotropic carbon encapsulated in an encapsulating material and as a result a robust and thermally efficient system is provided.

Embodiments of the invention will now be described, by way of example, with reference to the drawings of which:

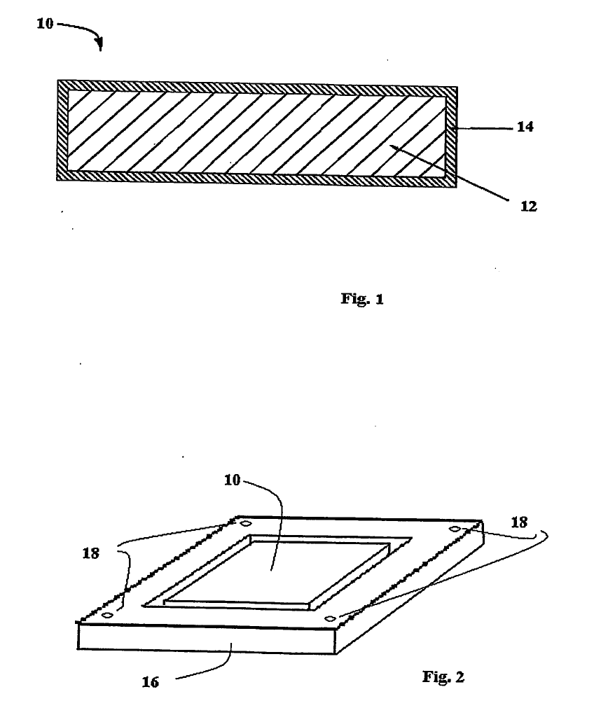

FIG. 1 is a sectional side view of a thermal management device according to the present invention;

FIG. 2 is a perspective view of the thermal management device of FIG. 1 in an outer defining template;

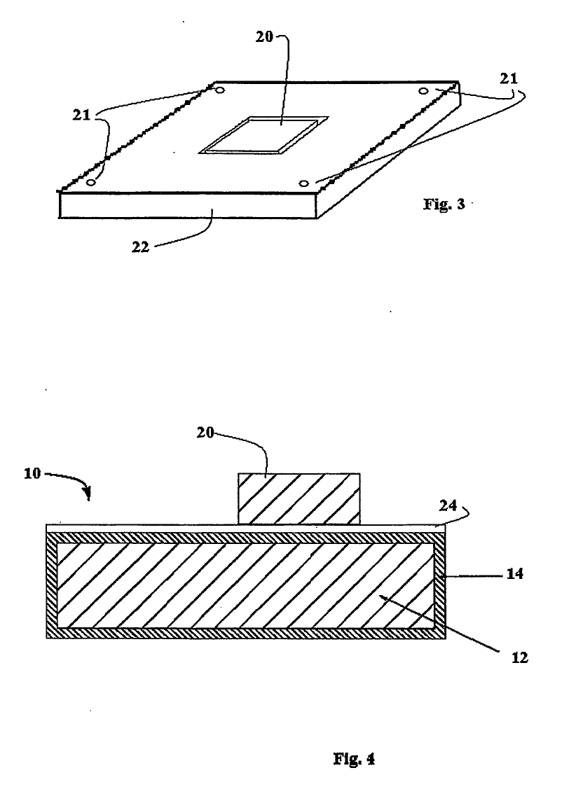

FIG. 3 is a perspective view of a semi-conductor device in an outer defining template;

FIG. 4 is a sectional view of the semi-conductor device of FIG. 3 mounted on the thermal management device of FIG. 1;

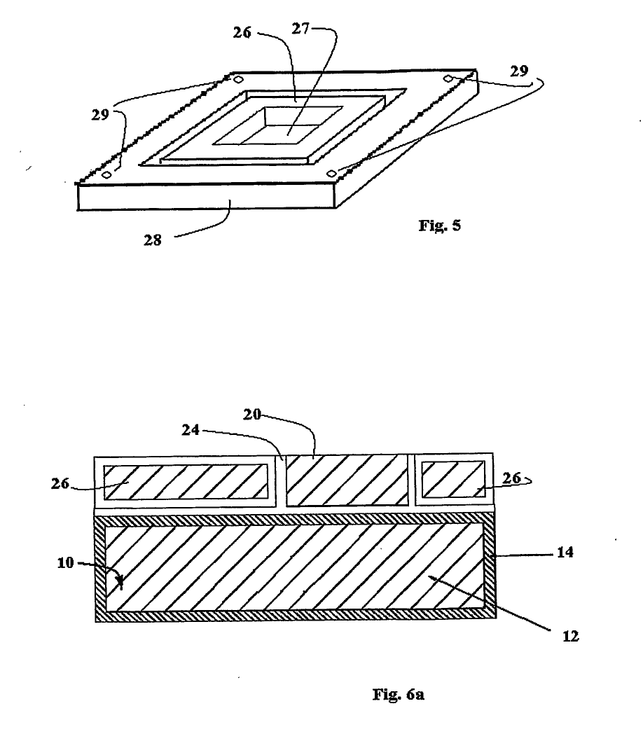

FIG. 5 is a perspective view of a further thermal management device in an outer defining template;

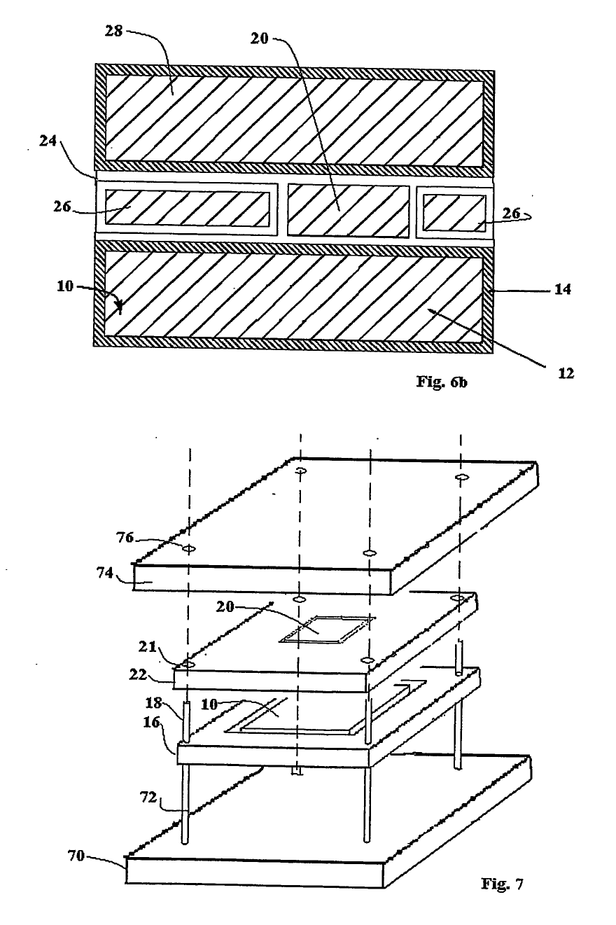

FIG. 6a is a sectional view of the semi-conductor device of FIG. 3 mounted with the thermal management devices of FIGS. 1 and 5;

FIG. 6b is a sectional view of the semi-conductor device of FIG. 3 encased between the thermal management devices of FIGS. 1 and 5 and a further thermal management device;

FIG. 7 is an exploded perspective view showing a fabrication technique;

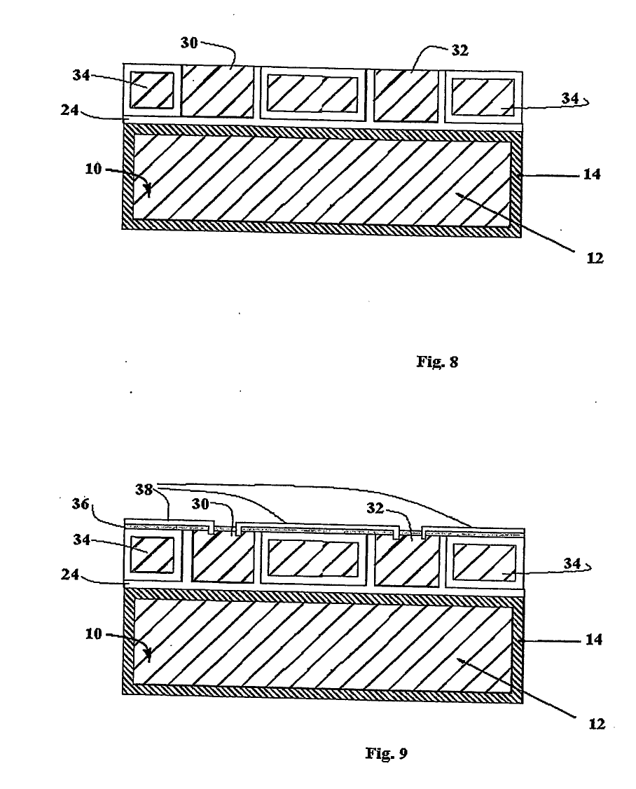

FIG. 8 is a sectional view of multiple semi-conductor devices partially encased in thermal management devices according to a second embodiment;

FIG. 9 is a sectional view of the embodiment of FIG. 8 with thin film layers added;

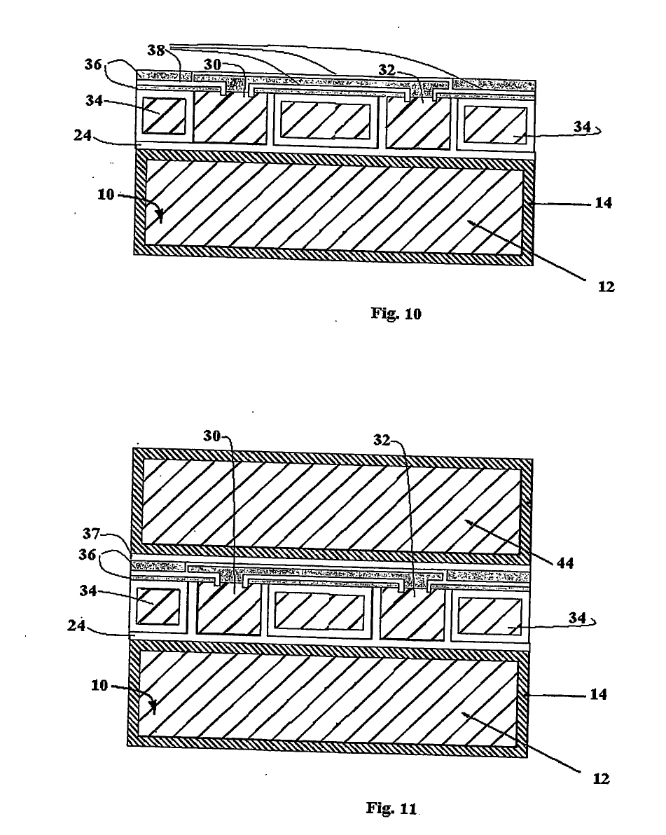

FIG. 10 is a sectional view of the embodiment of FIG. 8 with further thin film layers added;

FIG. 11 is a sectional view showing the embodiment of FIGS. 8 to 10 fully encased;

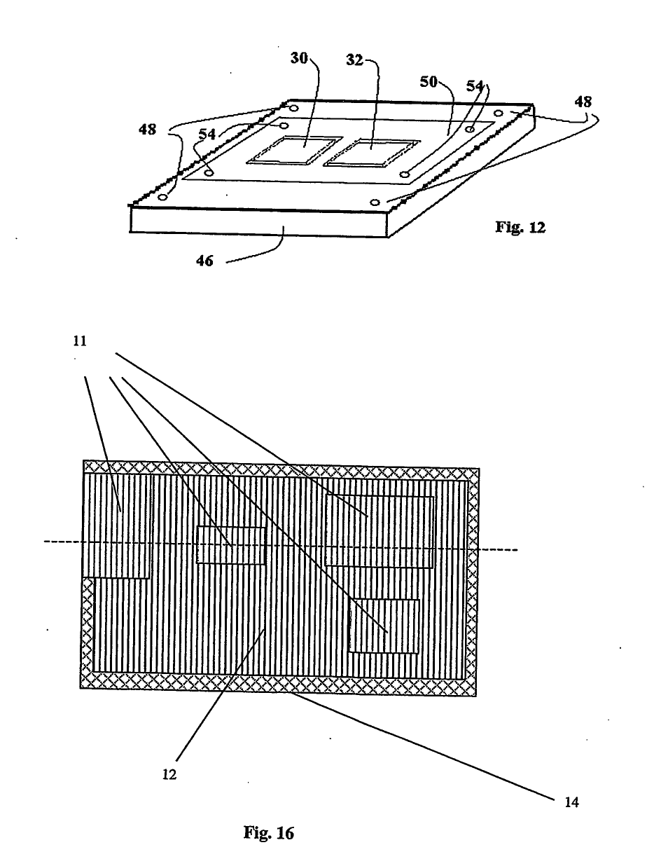

FIG. 12 is a side sectional view showing processing steps from an alternative approach to fabricating the embodiment of FIGS. 8 to 11; message

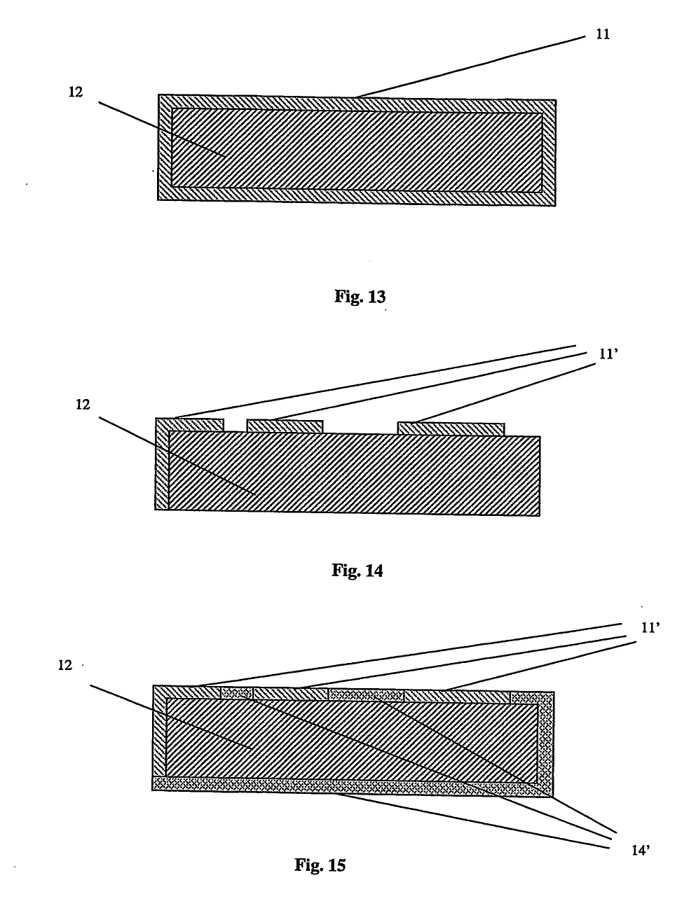

FIG. 13 and FIG. 14 show a side sectional view showing processing steps for fabricating a third embodiment shown in FIGS. 15 and 16;

FIG. 15 is a side sectional view of a third embodiment; and

FIG. 16 is a plan view of a third embodiment.

In overview an encased thermal management structure is provided in which a semi conductor component or other electrical device is encased in a thermal management device comprising plates of anisotropic carbon encapsulated in an encapsulating material. The thermal management device abuts each surface of the semi-conductor component and provides mechanical robustness while allowing efficient thermal transfer. The semi conductor component can be pre-fabricated in which case the structure includes appropriate holes allowing electrical contact leads to be accommodated. Alternatively the semi conductor component can be constructed as part of the encasement process either in situ or as a pre-processing stage.

The encased thermal management structure exhibits all of the properties of the thermal management devices described in WO00/03567 but enhances the possibility of providing three-dimensional structures with electrical connectivity. The structures can provide totally encased and customised electronic semi-conductor chip devices within individual packages to give improved robustness, security and replaceability. Where direct connections to the semi-conductor component is carried out during the encasement process, wire-bond interconnections can be removed altogether, hence decreasing production times and costs whilst providing devices that are more reliable and versatile. In particular this is achieved by incorporating direct thin-film electronic-hybrid processing or interfacing into the encasement sequence. Accordingly a new thermal management structure technology is provided for ASIC interfacing.

The nature and manner of fabrication of a thermal management device in which the device is encased is described fully in International patent application no. WO00/03567 and will be apparent to the skilled reader so that only a summary is provided here for ease of reference. In one embodiment a plate of thermalised pyrolitic graphite with mosaic or full ordering is coated with polyimide applied directly to the carbon surface for example using a brush. If necessary the coating is cured. Where required holes for electrical contact are formed for example by drilling prior to the coating step, encapsulating the drilled plate and then re-drilling the holes to a smaller diameter such that the carbon remains encapsulated.

The device can be attached to a substrate or used itself as a substrate for example for thin film circuits which can be deposited in any appropriate manner. Both sides of the device can be used and the device can form a base or substrate for a multi-layer circuit.

The thermal management device is thus constructed by direct molecular-level encapsulation of the carbon plate allowing interfacing with other heat transfer materials through micron-level fusing and providing an electronic hybrid technology allowing both single and double-side connectivity. The intrinsic thermal performance of the internal carbon substrate is preserved and thermal transfer characteristics expressed in the relevant parameter K/p (Thermal conductivity/density) are improved with respect to copper by a factor of between 18 to 20 and aluminium by nearly 90. At sub-zero temperatures the improvement factors can be dramatically increased further. The encapsulation layers are typically 20 microns and so for substrates of a thickness of a few hundred microns larger this represents a negligible increase in total volume and hence a negligible decrease in thermal conductivity preserving the fundamental thermal properties of the carbon plate whilst enhancing the mechanical properties such as sheer strength and surface integrity. The device provides robust structures with mechanical stability whilst maintaining low density and high in-plane thermal conductivity and a range of direct electrical processing to provide a new sector of high thermal conductivity hybrids.

Thermal management structures of the type described above form one part of the basis of the encased thermal management structures described herein as shown in more detail in the accompanying drawings which illustrate various approaches to constructing an encased electronic device.

In a first embodiment an encased thermal management structure includes a pre-fabricated or pre-packaged electronic device and is constructed as described below with reference to FIGS. 1 to 7.

Referring firstly to FIG. 1 a thermal management device designated generally 10 includes anisotropic carbon plate 12 and a polyimide encapsulating coat 14. The resulting unit is an effective dielectric substrate that will be isolated from any devices subsequently attached to its surface.

Referring to FIG. 2, the thermal management device 10 is received in and releasably attached for example by taping to a first outer defining template 16 that surrounds the device 10 and whose thickness defines the ultimate thickness of the corresponding layer. Locating dowel recesses 18 are provided on the template 16, as discussed in more detail below.

Referring to FIG. 3, an electronic component such as a pre-packaged semi conductor device 20 is provided in a second template 22 corresponding to template 16 and having dowel receiving recesses 21 to define the location of the device 20 with respect to the thermal management device 10.

Referring to FIG. 4 the two layers comprising the thermal management device 10 and the electronic component 20 are interfaced for example using standard interface epoxy-fusing to provide the structure shown in which the electronic component 20 is located on an epoxy layer 24 or other interfacing on the thermal management device 10. Alignment is carried out by location of the template using the dowel recesses 20, 21 as discussed in more detail below. Referring now to FIG. 5, a further thermal management device 26 having the same thickness as the electronic component 20, is cut in any appropriate manner with a hole 27 matching the profile of the component 20. The formation of the second thermal management device 26 can be in any appropriate manner—for example it can be cut first and then encapsulated as a whole. The second thermal management device 26 is received in a third template 28 which defines the thickness of the respective layer and which is locatable relative to the first template via dowel recesses 29. The second thermal management device 26 is then interfaced with the electronic component 20 and first thermal management device 10 as shown in FIG. 6a once again using epoxy fusing to give rise to a structure including a lower thermal management device layer 10 and a device 20 encapsulated on its side faces by device 26, bonded by an epoxy layer 24.

A third thermal management device 28 (shown in FIG. 6b) is provided on a fourth template in a similar manner to the steps described above and so not shown. The third thermal management device 28 is a mirror image of the first thermal management device 10 and is epoxy fused to the top of the structure shown in FIG. 6a to provide a structure as shown in FIG. 6b which the electronic component 20 is encased between thermal management devices 10, 26, 28 and bonded by epoxy layer 24.

The manner of fabrication will be well known to the skilled reader and is described only in summary here. Standard thermal management device interfacing techniques can be used. The relevant faces of the respective elements are printed with epoxy on the side required for interface and the, components are epoxy-fused and processed in any appropriate manner. The order of steps can be varied as appropriate and it will be appreciated that alternative approaches can be adopted.

One novel fabrication technique is described with reference to FIG. 7 which, for the purposes of clarity, is not shown to scale. As can be seen a base plate 70 which can be formed of, for example, aluminium has projecting upwardly from it elongate dowels 72. The first and second templates 16, 22 carrying the first thermal management device 10 and electronic component 20 respectively are mounted on the base plate 70 with the dowels 72 received in respective dowel recesses 18, 21. Because the templates 16 and 22 are accurately located on the dowels, precise positioning of the various components relative to one another can be achieved. Once the templates 16, 22 have been mounted a top plate 74 having a dowel recesses 76 is further provided and mounted on the dowels 72. The assembly is placed in a pressure jig and the top plate urged towards the base plate and the components are epoxy-fused and processed under pressure vacuum using conventional epoxy-fusing techniques.

It will be seen that the thickness of the respective templates hence defines the respective layer thicknesses including the epoxy interface layer. The specific arrangement shown in FIG. 7 provides a semi-conductor component 20 mounted on a thermal management device 10 as shown in FIG. 4. It will be seen that the remaining thermal management devices 26, 28 can be mounted on to the assembly thereafter either in separate steps or in a single step, via precision location of the respective templates and processing as described above. It will further be seen that common dowels 72 can be used for the templates and for the top plate 74, or one set of dowels can be used for the templates and another for the top plate as appropriate. Instead of retaining the part assembled device in its respective templates for further fabrication, a single part assembled device template can be used instead. In a further optimisation the base plate 70 and top plate 74 are biased away from one another by springs recessed into the base plate such that when pressure is applied the plates close towards each other and the springs are received fully within the base plate 70.

As a result of this arrangement precise and accurate location of the various components is achieved by the dowels 72 in association with linear bearings in the pressure plate 74 in the corresponding recesses 76. Where appropriate, if a component such as pre-packaged electronic component 20 requires electrical contact then an appropriate section of the encapsulating coat 14 of the thermal management device 10 (or any of the thermal management devices) can be removed by cutting away the required area to provide access to the graphite core. Similarly, apertures can be cut away in the second thermal management device 26 to allow access to electrical leads from the semi-conductor package 20 for external power and control.

As a result a fully encased pre-packaged semi-conductor device is provided. A heat sink attachment can be provided as appropriate and as will be familiar to the skilled reader, suitable for example for heat extraction by radiation and external convection.

In a second embodiment discussed below with reference to FIGS. 8 to 12, the requirement for wire interconnections is removed by including a device fabrication step as a processing or pre-processing step in the encasement process.

Referring to FIG. 8 it will be seen that in this case two semi-conductor components 30, 32 are provided interfaced with a lower thermal management device 10 and a suitably apertured further thermal management device 34. The processing steps to arrive at this configuration are as discussed above with reference to FIGS. 1 to 4 and, for the purposes of brevity, are not repeated here. The components 30, 32 can be individual components without the in-situ electrical interconnection in the pre-packaged device 20 described in the first embodiment.

Referring to FIG. 9 the first step of producing a multi layer electronic hybrid with direct and processed interconnections made between elements within a single active device or between devices, or between devices and passive interconnects is shown.

The various layers are constructed using standard masking and etching techniques which will be apparent to the skilled person and which, accordingly, are discussed only in summary here. The upper surface layer is masked and processed with polyimide to form the base layer for subsequent thin-film processing and electrical connectivity is provided by deposition of aluminium or other suitable materials such as copper layers. This provides the arrangement shown in FIG. 9 in which, in particular, a layer of polyimide 36 overlays the structure but allows connectivity through aluminium film connections 38 between the devices 30, 32 and to the exterior.

It is understood that electrical connections to the devices 30, 32 may also be provided on the side facing the thermal management device 10 by deposition of aluminium or other suitable materials such as copper layers on the surface of the polyimide encapsulation 14 of the thermal management device 10 that is facing devices 30 and 32. Thus, aluminium, copper or other suitable material electrical connections may be provided situated in between the devices 30, 32 and the thermal management device 10.

Further customised electrical connectivity, for example required for the powering control under the semi conductor device, is added by providing further interconnections, repeating the etching and masking steps described above and as shown in FIG. 10 in which a second layer is provided. As can be seen a further polyimide layer 36 and a further electrical interconnections 38 have been deposited.

Complete encasement of the devices 30, 32 and interconnections 36, 38 is then achieved by encasing the structure with an upper thermal management device in the manner described with reference to FIGS. 6 and 7 as can be seen from FIG. 11 in which a further thermal management device 44 encases the upper surfaces of semi-conductor components 30, 32, bonded by a further epoxy layer 37. It will be appreciated that the multi-layer thin film extends beyond the encased structure to allow connectivity.

An alternative manner of fabricating the structure of the second embodiment is discussed with reference to FIG. 12 in which the electrical connectivity processing steps for the semi-conductor devices and the inter connections with the devices are carried out as a separate processing or pre-processing step in the fabrication of the structure as a whole. In particular, the semi-conductor devices 30, 32 are provided inverted in a template 46 with dowel receiving recesses 48 for the dowels of a base plate 70 as shown in FIG. 7. The template 46 comprises a combined aluminium template and back substrate having flatness, spatial geometry and doweling to a suitably high precision. The arrangement hence provides both the substrate material for the multi-layer thin film processing and the required positioning of the active devices. A multi-layer thin film 50 is constructed on the template 46 by deposition and etching of successive polyimide and aluminium layers as discussed in relation to FIGS. 9 and 10. In addition dowel recesses 54 are formed in the polyimide layers of the thin film 50 to allow correct relative alignment of the hybrid structure with respect to the encasing structure of thermal management devices in the epoxy-fusing processing as described below.

After the multi-layer electronic hybrid structure comprising components 30, 32 and thin film 50 has been processed by fabrication on template 46, the aluminium template 46 is removed by etching (and suitable masking of any interconnections) to provide a flex-hybrid assembly with all necessary electrical connectivity integrated for the semi-conductors 30, 32. The electrical connectivity testing of the active hybrid structure can then be carried out before the devices are encapsulated into the anisotropic carbon substrates during processing. The assembly steps for constructing the encased device according to this approach are effectively as above except that the flex hybrid is provided as a doweled item rather than being fabricated in-situ. In particular the hybrid structure is mounted on the second thermal management device 34 in a first step, located by dowel recesses 54 in the manner discussed above, providing the required level of flatness. The second thermal management device is then mounted with the first and third thermal management devices 10, 44. All the components are epoxy fused as discussed above and it will be noted that bonds between the side faces of the devices 30, 32 and the second thermal management device 34 are formed by natural flow of the epoxy. After fabrication redundant parts of the flexi-hybrid assembly extending beyond the thermal management devices 10, 34, 44 are cut away leaving only the portions required for interconnectivity.

Approaches to providing thin-film layers are discussed above and are also found in PCT/WO00/03567 and the optimisations discussed therein can be adopted as appropriate. The aluminium may be directly deposited onto the polyimide (or other material) of the thermal management device or aluminium substrate typically using thin film aluminium techniques so that layers having thicknesses of 5 μm can be deposited. Because the coated surface of the thermal management device is flat the resolution of the lithography used to deposit the aluminium is good meaning that small features can be readily defined. Polyimide can then be applied over the aluminium by spinning or screen printing providing thicknesses for the polyimide of as little as 8 μm. Using standard fabrication techniques, holes are then defined through the polyimide in appropriate places so that subsequent layers of metal that fill these holes can provide electrical contact to the aluminium. Between the subsequent layers of metal are typically layers of polyimide.

In a third embodiment shown in FIGS. 13 to 16, the thermal management device shown in FIG. 1 can also be produced with some fraction of its surface having the carbon plate directly interfaced to metal or another electrically conductive material. The areas and the thickness of the metal regions can be customised, and if required, such areas can remain uncoated in the final device. This can be advantageous, for example if the metal surface is to be used for attachment of external devices such as active semiconductors, through brazing or by the use of appropriate adhesive materials.

To produce such a device, the cleaned plate 12 is coated to a thickness of, for example, a few microns up to tens of microns with a metal (for example copper) using a chemical deposition process, electroplating, sputtering or a similar process. The coating can be made as a single layer of a metal, multiple sandwiched layers of the same or different metals, a combination of different metals or of an alloy. It can comprise two or more sub-layers, each produced by one or more of the above techniques.

After coating the surfaces of the carbon-metal structure can be masked with the desired pattern for the final metal configuration, and metal removed from the unwanted areas or regions by etching. After the etching the desired surface areas of metal 11′ remain directly interfaced to the carbon plate.

The subsequent encapsulation of the carbon plate, preferably with polyimide, can then be made (excluding the patterned metal areas). The regions 14′ with polyimide coating then provide electrical insulation between the carbon and the outer surface, while those left exposed provide direct metal connection to the carbon plate. If desired, the whole plate including the metal areas can be coated and the coating may subsequently be removed from the metal areas.

Alternatively, the metal areas may be left covered with coating, in which case they would not provide an electrically conducting connection to the carbon plate 12, but could still be employed as an electromagnetic screening material in order to screen the whole or part of carbon plate 12. For example, this may be achieved by applying a mesh of metallic tracks on the surface of carbon plate 12 using the technique as outlined above and then encapsulating the entire device 10.

FIG. 13 illustrates the device after the initial coating of the carbon plate 12, with a thin layer of metal 11. FIG. 14 shows the desired areas of metal 11′ after etching and FIG. 15 shows the plate with the polyimide coating 14′ and the metal areas 11′ exposed. FIG. 16 is a plan view of a device according to the third embodiment, with FIG. 15 representing a cross-section along the dashed line.

A thermal management device comprising a plate of anisotropic carbon encapsulated in an encapsulating layer, the layer comprising discrete elements of electrically insulating material and of electrically conducting material, can thus be manufactured using a method of fabricating a thermal management device including coating an anisotropic carbon plate with an electrically conducting material forming an conductive coating; removing parts of the conductive coating and encapsulating the resulting structure with electrically insulating material.

In relation to FIG. 9, the possibility of providing electrical connectivity to devices 30, 32 between the devices and the thermal management device 10 was discussed, such that as a result devices 30, 32 are not electrically connected to the carbon plate of the thermal management device 10. By contrast, the thermal management device of the third embodiment may be employed to provide electrical conductivity between the devices 30, 32 and the carbon plate 12 by connecting devices 30, 32 to exposed areas of metal 11′ using aluminium or copper tracks or any other suitable electrical connection.

It will be seen, therefore, that the invention provides a significantly improved, robust and thermally efficient device packaging technique in which, where thin-film structures are used, no internal bond wires are required allowing improved and more robust electrical inter-connectivity. Because the flex hybrid assembly is self-contained it can be provided off-the-shelf. Yet further, bearing in mind that the majority of heat generated in semi-conductors typically originate from the top few microns or tens of microns of the structure, the encapsulation process provides optimised thermal contact with the most relevant parts of the devices.

It will be appreciated that aspects from different embodiments can be interchanged or juxtaposed as appropriate. Although application of the thermal management device to semi-conductor and other electrical device packaging as discussed, the device can be equally well used in any appropriate cooling/heat-transfer environment and in combination with any of the optimisations discussed in WO00/03567. Similarly the specific materials and fabrication techniques discussed can be varied as appropriate and the various steps can be carried out in any appropriate order. The encasement technique can be applied to single or multiple components of similar or varying shapes and profiles with appropriate reconfiguration of the thermal management devices encasing them.

1. An electrical system comprising an electronic device encased in a thermal management device, the thermal management device comprising anisotropic carbon encapsulated in an encapsulating material.

2. An electrical system as claimed in claim 1 in which the thermal management device comprises multiple encasing elements adjacent each surface of the electronic device.

3. An electrical system as claimed in claim 1 in which encapsulating material is cut away to allow electrical contact to the anisotropic carbon.

4. An electrical system as claimed in claim 1 in which the electronic device is pre-packaged.

5. A system as claimed in claim 4 in which the thermal management device accommodates electrical contacts to the electronic device.

6. A system as claimed in claim 1 in which the electronic device includes discrete components having a single or multiple-layer thin film interconnection.

7. A system as claimed in claim 1 in which the anisotropic carbon is pyrolitic graphite or thermalised pyrolitic graphite.

8. A system as claimed in claim 1 in which the encapsulating material is applied directly to the anisotropic carbon and improves the rigidity of the carbon.

9. A system as claimed in claim 1 in which the encapsulating material is polyimide or epoxy-resin or acrylic or polyurethane or polyester or any other suitable polymer.

10. A method of fabricating an electrical system comprising the steps of encasing an electronic device in a thermal management device comprising anisotropic carbon encapsulated in an encapsulating material.

11. A method as claimed in claim 10 in which the thermal management device comprises multiple encasing elements and comprising the steps of locating the electronic device with its surface adjacent the encasing elements.

12. A method as claimed in claim 10 the electronic device comprises discrete components and in which a single or multiple layer thin film interconnection between the components is formed prior to encasing the electronic device.

13. An electrical system fabrication apparatus comprising first and second end plates and a guide structure for guiding relative positioned movement of the end plates and locating electrical system components for fabrication of an electrical system there between.

14. An apparatus as claimed in claim 13 further comprising a pressure component for urging the first and second end plates towards one another.

15. An apparatus as claimed in claim 13 further comprising biasing means arranged to bias the first and second end plates away from one another.

16. A method of fabricating an electrical system comprising the steps of mounting a thermal management device on a guide structure on an end plate, mounting an electronic device on the guide structure and mating the thermal management device and the electronic device.

17. A method as claimed in claim 16 in which the thermal management device comprises multiple encasing elements and comprising the steps of mating the electronic device with the encasing elements to encase the electronic device in the thermal management device.

18. An electronic device comprising discrete components having a single or multiple layer thin film interconnection in which the film includes locating elements for locating the device relative to a component with which it is to be mated.

19. A method of fabricating an electronic device having discrete components comprising the steps of mounting the discrete components in a template and fabricating a single or multiple layer thin film interconnection on the template between the discrete components.

20. A method as claimed in claim 19 further comprising the step of removing the template.

21. A method as claimed in claim 19 further comprising the step of forming locating elements on the film.

22. (canceled)

23. A method of fabricating a thermal management device including coating an anisotropic carbon plate with an electrically conducting material forming a conductive coating; removing parts of the conductive coating such as to provide an electrically conductive region on the surface of the thermal management device; and encapsulating the resulting structure with electrically insulating materials such as to provide an electrically insulated region on the surface of the thermal management device.

24. A method as claimed in claim 23, whereby the entire device including the conductive region is encapsulated with an electrically insulating material.

25. A method as claimed in claim 24, whereby the electrically insulating material is subsequently removed from the conductive region.

26. A method as claimed in claim 23, whereby the conductive region is left unencapsulated.

27. A method as claimed in claim 23, wherein the conductive coating comprises a metal, a combination of metals, layers of the same or different metals or an alloy.

28. A thermal management device comprising a plate of anisotropic carbon encapsulated in an encapsulating layer, the layer comprising discrete regions of electrically insulating material and of electrically conducting material.

29. A device as claimed in claim 28, wherein the electrically conducting material comprises a metal, a combination of metals, layers of the same or different metals or an alloy.
